(19) United States
(12) Patent Application Publication
(10) Pub. No.: US 2018/0143414 A1
(43) Pub. Date: May 24, 2018

(54) METHOD OF PRODUCING A LENS FOR AN OPTOELECTRONIC LIGHTING DEVICE

(71) Applicant: OSRAM Opto Semiconductors GmbH, Regensburg (DE)

(72) Inventors: Hansjoerg Schoell, Bad Abbach (DE); Stephan Blaszczak, Freyburg (DE); Thomas Zollner, Duggendorf (DE)

(21) Appl. No.: 15/572,828

(22) PCT Filed: May 10, 2016
(86) PCT No.: PCT/EP2016/060415

§ 371 Date: Nov. 9, 2017

(30) Foreign Application Priority Data
May 13, 2015 (DE) 10 2015 107 516.4

(51) Int. Cl. G02B 19/00; H01L 33/58; H01L 31/0232; G02B 27/09; H01L 33/54; H01L 33/56

(52) U.S. Cl. CPC G02B 19/0061; H01L 33/58; H01L 31/0232; H01L 2933/0058; H01L 33/54; H01L 33/56; G02B 27/0955

(57) ABSTRACT

A method of producing a lens for an optoelectronic lighting device, wherein the optoelectronic lighting device includes an optoelectronic semiconductor component having a light-emitting surface, including applying a curable lens material to the light-emitting surface, and curing the lens material to form a lens from a cured lens material, wherein after the application and before or during the curing, the light-emitting surface is arranged into a position in which a normal vector of the light-emitting surface oriented in the direction of the applied lens material and a normal force of a weight acting on the light-emitting surface are parallel to one another so that the lens material at least partially cures in the position.

### TECHNICAL FIELD

This disclosure relates to a method of producing a lens for an optoelectronic lighting device and an optoelectronic lighting device.

### BACKGROUND

It is usual to use a lens for an optical imaging of light emitted by a light-emitting diode. Such a lens may, for example, be formed directly on a light-emitting surface of the light-emitting diode. For this, silicone, for example, may be applied to the light-emitting surface by a potting process and subsequently cured.

As a result of the gravitational force, there forms a lens geometry in the shape of a flattened hemisphere with a generally elliptical cross section. An outcoupling of light from the light-emitting diode is thereby limited.

It could therefore be helpful to provide an efficient outcoupling of light from an optoelectronic semiconductor component.

### SUMMARY

We provide a method of producing a lens for an optoelectronic lighting device, wherein the optoelectronic lighting device includes an optoelectronic semiconductor component having a light-emitting surface, including applying a curable lens material to the light-emitting surface, and curing the lens material to form a lens from a cured lens material, wherein after the application and before or during the curing, the light-emitting surface is arranged into a position in which a normal vector of the light-emitting surface oriented in the direction of the applied lens material and a normal force of a weight acting on the light-emitting surface are parallel to one another so that the lens material at least partially cures in the position.

We also provide a method of producing a lens for an optoelectronic lighting device, wherein the optoelectronic lighting device includes an optoelectronic semiconductor component having a light-emitting surface, including applying a curable lens material to the light-emitting surface, and curing the lens material to form a lens from a cured lens material, wherein after the application and before or during the curing, the light-emitting surface is arranged into a position in which a normal vector of the light-emitting surface oriented in the direction of the applied lens material and a normal force of a weight acting on the light-emitting surface are parallel to one another so that the lens material at least partially cures in the position, before the application, a dam running around the light-emitting surface completely so that the dam is therefore uninterrupted, is formed for the lens material to be applied.

We further provide an optoelectronic lighting device including an optoelectronic semiconductor component having a light-emitting surface, and a lens formed on the light-emitting surface from a lens material having at least partially cured in a position in which a normal vector of the light-emitting surface oriented in the direction of a lens material applied to the light-emitting surface and a normal force of a weight acting on the light-emitting surface are parallel to one another.

### BRIEF DESCRIPTION OF THE DRAWINGS

FIG. 1 shows a flow diagram of a method of producing a lens for an optoelectronic lighting device.

FIG. 2 shows an optoelectronic lighting device.

FIG. 3 shows a further optoelectronic lighting device after applying a curable lens material.

FIG. 4 shows the optoelectronic lighting device from FIG. 3 during curing.

FIG. 5 shows an example of one of our lenses.

FIG. 6 shows a known lens.

FIG. 7 shows a further example of one of our lenses.

FIG. 8 shows a further known lens.

FIGS. 9 and 10, respectively, show an optoelectronic lighting device in different positions.

### LIST OF REFERENCE SIGNS

101 applying
103 arranging
105 curing
201 optoelectronic lighting device
203 optoelectronic semiconductor component
205 light-emitting surface
207 lens
301 optoelectronic lighting device
303 optoelectronic semiconductor component
305 light-emitting surface
307 dam
309 lens material
311 weight
313 normal vector
315 diameter
317 height
501 cured lens
503 light-emitting surface
505 optoelectronic semiconductor component
507 optoelectronic lighting device
601 cured lens
701 cured lens
703 optoelectronic lighting device
801 cured lens
901 optoelectronic lighting device
903 optoelectronic semiconductor component
905 light-emitting surface
907 weight
909 lens material
911 normal vector
913 normal force
915 tangential force

### DETAILED DESCRIPTION

Our method of producing a lens for an optoelectronic lighting device having an optoelectronic semiconductor component having a light-emitting surface may comprise the following steps:
applying a curable lens material to the light-emitting surface, and
curing the lens material to form a lens from a cured lens material, wherein
after the application and before or during the curing, the light-emitting surface is arranged into a position in which a normal vector of the light-emitting surface oriented in the direction of the applied lens material and a normal force of a weight acting on the light-emitting surface are parallel to one another so that the lens material at least partially cures in the position.

Our optoelectronic lighting device may comprise:
an optoelectronic semiconductor component having a light-emitting surface, and
a lens formed on the light-emitting surface from a lens material having at least partially cured in a position in which a normal vector of the light-emitting surface oriented in the direction of a lens material applied to the light-emitting surface and a normal force of a weight acting on the light-emitting surface are parallel to one another.

The fact that the lens material at least partially cures in the position has the effect in particular of bringing about the technical advantage that a lens that has an increased aspect ratio (height of the lens÷diameter of the lens) compared to known methods can be produced. This is brought about in particular by the weight of the applied lens material causing a stretching of the lens material in this position. The applied lens material tries to drip from the light-emitting surface. In known methods, however, the weight tends rather to produce a lens geometry in the shape of a flattened hemisphere. This increased aspect ratio consequently allows in particular an efficient and improved outcoupling of light from the optoelectronic semiconductor device to be brought about in an advantageous way. Consequently, an efficient outcoupling of light from the optoelectronic semiconductor component is made possible in an advantageous way.

The semiconductor component may be a light-emitting diode (LED). The light-emitting diode may, for example, be an organic or inorganic light-emitting diode.

A number of optoelectronic semiconductor components may, for example, be formed identically or in particular differently. The statements made in connection with an optoelectronic semiconductor component apply analogously to a number of optoelectronic semiconductor components, and vice versa.

The light-emitting surface may be a surface of a conversion layer. That is to say therefore, for example, that the semiconductor component may comprise a conversion layer. A conversion layer is in particular converts electromagnetic radiation of a first wavelength or a first wavelength range into an electromagnetic radiation of a second wavelength or a second wavelength range, the second wavelength being different from the first wavelength or the second wavelength range being at least partially, in particular completely, different from the first wavelength range. A conversion layer therefore has a conversion function, that it to say to convert electromagnetic radiation. The electromagnetic radiation to be converted may be referred to, for example, as a primary light or as a primary radiation. The electromagnetic radiation converted by the conversion layer may be referred to, for example, as a secondary light or as a secondary radiation.

The conversion layer may, for example, comprise a phosphor and/or an organic and/or an inorganic fluorescent or luminescent material.

The weight is the force caused by the effect of a gravitational field on a body, here for example, the light-emitting surface or the applied lens material. In a rotating system of reference of a celestial body, for example, the earth, this gravitational field is made up of a gravitational component and a centrifugal component, which is smaller compared to the gravitational component. The weight is directed perpendicularly downward, which corresponds almost, but not exactly (because of the centrifugal component) to the direction of the center of the earth. The weight is therefore the product of the mass of the body by the acceleration due to gravity.

The perpendicular direction refers to a spatial direction of the acceleration due to gravity, which therefore points downward, that is to say approximately, if not exactly, in the direction of the center of the earth.

Every force acting on a surface can be broken down into the components normal force and tangential force. The normal force is perpendicular to the surface, that is to say in the direction of a normal vector. That is to say therefore that the weight can be broken down into the components normal force and tangential force.

A normal vector is a vector that is orthogonal, that is to say at right angles or perpendicular, to a straight line, a curve, a plane or a surface. A surface may, for example, have two normal vectors that point in opposite directions.

The normal vector of the light-emitting surface oriented in the direction of the applied lens material, and the normal force of the weight acting on the light-emitting surface are parallel to one another when the light-emitting surface is in the position. This normal vector of the light-emitting surface and this normal force therefore point in a common direction. They are therefore collinear and parallel.

In known methods, the lens material was cured when the light-emitting surface is in a position in which this normal vector and this normal force are antiparallel to one another. Therefore, the normal vector and the normal force point in opposite directions. Although they are still collinear, they are antiparallel.

Curing means in particular an irreversible transition of the lens material from a liquid state into a solid state by a crosslinking. Crosslinking refers in macromolecular chemistry to reactions in which a multiplicity of individual macromolecules are interlinked to form a three-dimensional network. The interlinkage may be brought about, for example, directly during the buildup of the macromolecules and/or, for example, by reactions on already existing polymers. The crosslinking process has the effect of changing properties of the crosslinked substances, here for example, the lens material. For example, an increase in the hardness and/or the toughness and/or the melting point and/or a lowering of the solubility are intended.

The lens material may comprise one or more silicones or is formed by one or more silicones.

Silicone is a term for a group of synthetic polymers in which silicon atoms are crosslinked by oxygen atoms.

The use of one or more silicones for the lens material to be cured has the effect in particular of bringing about the technical advantage that an efficient application of the lens material to the light-emitting surface can be brought about. In particular, as a result the lens material can be applied to the light-emitting surface in potting processes known per se.

The application process may comprise dispensing and/or pouring the lens material.

The weight may be substantially perpendicular to the light-emitting surface so that the normal vector corresponds substantially to the weight.

This has the effect in particular of bringing about the technical advantage that a substantially symmetrical geometry of the lens can be brought about. The symmetry relates here to the normal vector of the light-emitting surface. Thus, for example, a parabolic shape of the lens can be achieved.

That the normal vector corresponds substantially to the weight comprises in particular when the normal vector corresponds exactly to the weight. That is to say therefore that the weight is exactly perpendicular to the light-emitting surface. However, the wording “substantially” also comprises those cases that deviate from this perfect orthogonality within the range of production tolerances. Thus, the wording “substantially” comprises in particular deviations of ±10°, in particular of ±5°, preferably of ±1°, in relation to the normal vector.

That is to say therefore in particular that, according to one example, an angle between the weight and the normal vector is 0° to 10°, for example, 0° to 5°, in particular 0° to 1°.

Before the application, a dam that runs at least partially around the light-emitting surface may be formed for the lens material to be applied.

This has the effect in particular of bringing about the technical advantage that a surface limitation can be produced so that the applied lens material remains on the light-emitting surface and, for example, does not flow down from it. This has the effect, for example, that efficient production can be brought about. In particular, lens material can thereby also be prevented from flowing to regions of the lighting device at which wetting with lens material is not desired.

The dam may comprise one or more silicones. In particular, the dam is formed by one or more silicones.

The dam has a height of 400 μm to 600 μm with respect to the light-emitting surface. This has the effect in particular of bringing about the technical advantage that a sufficiently high surface limitation can be produced to apply sufficient lens material to the light-emitting surface in an advantageous way to produce a sufficiently large lens.

The dam may have a height of 500 μm with respect to the light-emitting surface.

The dam may run around the light-emitting surface completely. The dam is therefore uninterrupted.

Before the arranging of the light-emitting surface into the position, the applied lens material may be pre-cured.

This has the effect in particular of bringing about the technical advantage that undesired movements of the applied lens material when the light-emitting surface is being arranged into the position can be prevented or at least reduced. In particular, excessive dripping of the lens material from the light-emitting surface can be prevented thereby.

The pre-curing and/or the curing may comprise irradiation of the applied lens material with electromagnetic radiation and/or heating of the lens material to a temperature of 140° C. to 160° C., in particular 150° C., for a time of 3400 s to 3800 s, in particular 3600 s. That is to say therefore in particular that the applied lens material is, for example, kept at a temperature of 140° C. to 160° C., in particular 150° C., for a time of 3400 s to 3800 s, in particular 3600 s to pre-cure and/or cure the applied lens material.

Between 10 mg and 20 mg, in particular 10 mg or 20 mg, of curable lens material is applied to the light-emitting surface.

This has the effect in particular of bringing about the technical advantage that a sufficiently large lens can be produced as a result of the filling amount used.

“Sufficiently large” means in particular that the lens produced is of a size suitable for the intended use. The size in this case depends, for example, on the wavelength to be outcoupled of the electromagnetic radiation emitted by the semiconductor component. For example, the size depends on which emission angle the electromagnetic radiation is intended to have.

The lens of the optoelectronic lighting device may be produced by the method of producing a lens for an optoelectronic lighting device.

The semiconductor component may be formed as a semiconductor chip.

Statements that are made in connection with the method apply analogously to examples with regard to the lighting device, and vice versa. That is to say therefore that technical functionalities for the lighting device arise analogously from corresponding technical functionalities of the method, and vice versa.

Properties, features and advantages described above and the manner in which they are achieved become clearer and more clearly understandable in connection with the following description of the examples, which are explained in greater detail in connection with the drawings.

In the text that follows, the same reference signs are used for the same features.

FIG. 1 shows a flow diagram of a method of producing a lens for an optoelectronic lighting device.

The optoelectronic lighting device has an optoelectronic semiconductor component. The optoelectronic semiconductor component comprises a light-emitting surface. The method comprises the following steps:
According to a step 101, a curable lens material is applied to the light-emitting surface of the optoelectronic semiconductor component. For example, the curable lens material may be poured or dispensed onto the light-emitting surface. That is to say therefore that the application of the curable lens material may comprise a potting process.
In a step 103, the light-emitting surface is arranged into a position in which a normal vector of the light-emitting surface oriented in the direction of the applied lens material and a normal force of a weight acting on the light-emitting surface are parallel to one another.
In a step 105, the lens material cures in this position.

In an example not shown, the light-emitting surface is arranged into the position during curing. That is to say therefore that a curing process or a curing of the lens material has already begun when the light-emitting surface is arranged into the position.

The arranging of the light-emitting surface into the position has the effect in particular of bringing about the technical advantage of producing lens geometries that generally cannot be achieved if during curing the normal vector and the normal force are antiparallel to one another.

If the normal vector and the normal force are parallel to one another, it is thus possible in an advantageous way, for example, for parabolic shapes to be achieved for the lenses. If, on the other hand, the normal force and the normal vector are antiparallel to one another, generally flattened hemispheres are obtained for the lenses.

It is also possible in an advantageous way to influence a lens shape by the amount of curable lens material applied to the light-emitting surface.

Our method makes it possible in an advantageous way for almost hemispherical lenses to be produced easily and efficiently. It has previously only been possible for almost hemispherical lenses to be produced with very laboriously injection-molded lenses. This however requires a special potting mold, which is technically complex and cost-intensive. Furthermore, only selected injection-moldable silicones can be used for such injection-molding processes in special injection molds. These disadvantages can be overcome in an advantageous way by the method.

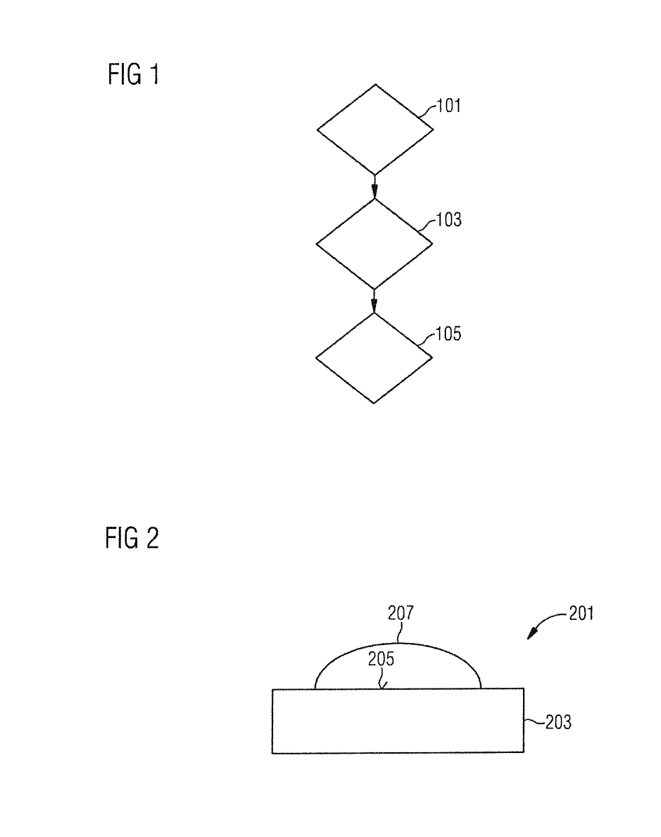

FIG. 2 shows an optoelectronic lighting device 201.

The optoelectronic lighting device comprises an optoelectronic semiconductor component 103 that, for example, may be formed as a light-emitting diode. The semiconductor component 203 comprises a light-emitting surface 205. That is to say therefore that during operation of the optoelectronic semiconductor component 203 electromagnetic radiation, for example, light is emitted by the light-emitting surface 205.

On the light-emitting surface 205 there is formed or arranged a lens 207 formed from a lens material having at least partially cured in a position in which a normal vector of the light-emitting surface oriented in the direction of a lens material applied to the light-emitting surface 205 and a normal force of a weight acting on the light-emitting surface 205 are parallel to one another.

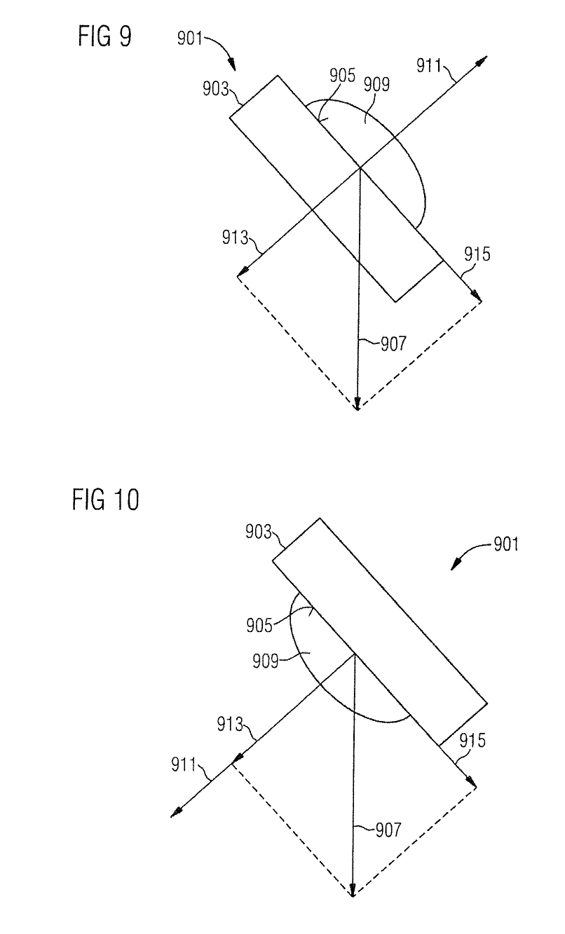

With regard to a graphic representation of the normal vector and the normal force and also of the weight, reference is made in particular to FIGS. 9 and 10 and to the corresponding statements made.

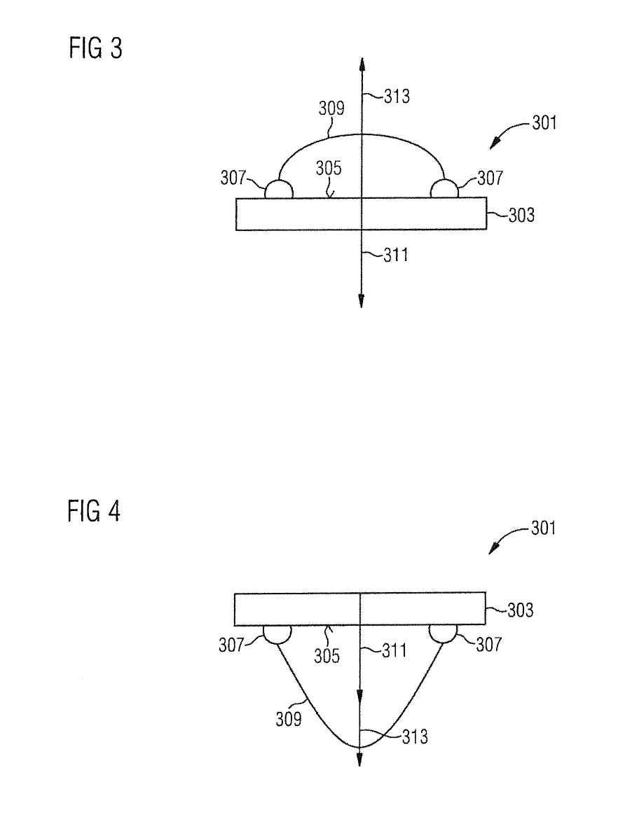

FIG. 3 shows an optoelectronic lighting device 301 in a lateral sectional view.

The optoelectronic lighting device 301 comprises an optoelectronic semiconductor component 303 having a light-emitting surface 305. Formed around the light-emitting surface 305 is a dam 307 that encloses the light-emitting surface 305.

A curable lens material 309 has been applied to the light-emitting surface 305. The dam 307 prevents unfavorable flowing of the applied lens material 309 and acts as a limitation for the lens material 309 so that it does not flow down from the light-emitting surface 305.

In the position of the light-emitting surface 305 that is shown in FIG. 3, the weight 311 and the normal vector 313 are antiparallel to one another. In such a position, it is advantageous and provided in particular that curable lens material is applied to the light-emitting surface 305.

If, however, the applied lens material 309 is cured in this position according to FIG. 3, this has the effect of forming a cured lens having the shape of a flattened spherical shape with generally an elliptical cross section. An outcoupling of light from the optoelectronic component 303 is limited by this geometry.

The light-emitting surface 305 may be arranged into a position in which the normal vector 313 and a normal force of the weight 311 are parallel to one another. This is shown by FIG. 4. In FIG. 4, the weight 311 is perpendicular to the light-emitting surface 305 so that this normal force corresponds to the weight 311, and is therefore not provided with a reference sign of its own and not explicitly represented. In the position shown in FIG. 4, consequently, the normal vector 313 and the weight 311 are parallel to one another.

In this position, the weight 311 brings about the effect that the applied lens material 309 stretches and forms a parabolic shape. In this position, the applied lens material 309 is cured.

FIG. 5 shows a further cured lens 501 produced by our method.

The lens 501 is arranged on a light-emitting surface 503 of an optoelectronic semiconductor component 505 of an optoelectronic lighting device 507.

The lens 501 was cured while the light-emitting surface 503 was in a position analogous to FIG. 4. That is to say therefore that during the curing, the weight 311 and the normal vector 313 are parallel to one another so that the lens shape shown in FIG. 5 could form and solidify. After the curing, the light-emitting surface 503 can be brought back into the position shown in FIG. 5 (normal vector 313 and weight 311 antiparallel to one another), without the lens 501 losing its shape.

A height of the lens 501 is indicated by a double-headed arrow with the reference sign 317. A diameter of the lens 501 is indicated by a double-headed arrow with the reference sign 315.

An aspect ratio of the lens 501 is therefore equal to the height 317 divided by the diameter 315.

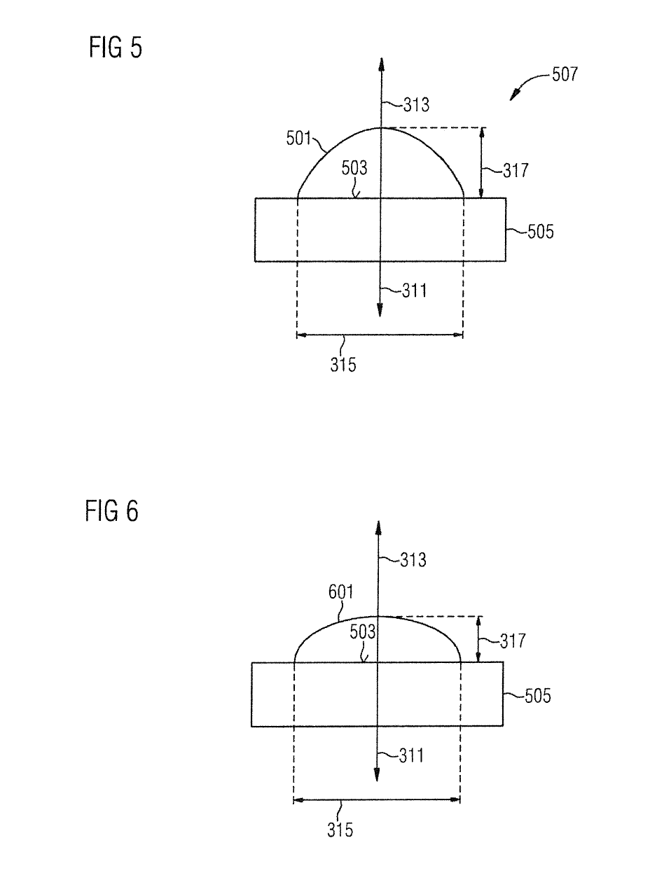

FIG. 6 shows a cured lens 601, this lens 601 having been produced according to a known method. In the known method, the light-emitting surface 503 was arranged in a position analogous to FIG. 3 during curing of the lens material. That is to say therefore that during the curing, the weight 311 and the normal vector 313 were antiparallel to one another. It is evident that the lens shape of the cured lens 601 is more flattened compared to the lens shape of the cured lens 501 according to FIG. 5. A corresponding aspect ratio is consequently lower compared to the optoelectronic lighting device 507 according to FIG. 5.

To produce lens 501 according to FIG. 5, and to produce the lens 601 according to FIG. 6, 10 mg of curable lens material were applied to each of the light-emitting surfaces 503. In an example not shown, a height of a dam with respect to the light-emitting surface 503 is 500 μm. A diameter 315 for both lenses 501, 601 is, for example, 4 mm.

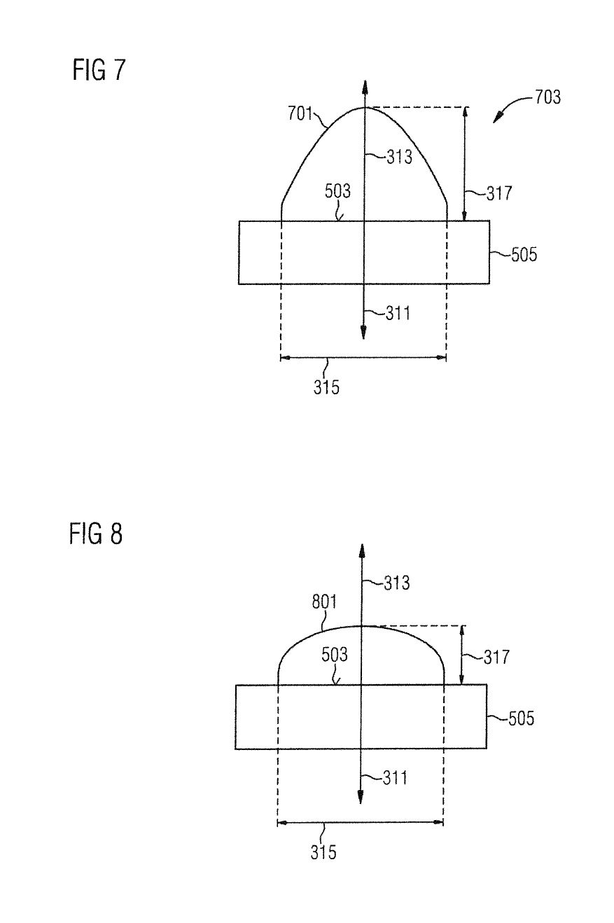

FIGS. 7 and 8 respectively show a lens 701 cured according to our method and a lens 801 cured according to a known method.

By analogy with FIG. 5, producing the lens 701 in FIG. 7 the applied lens material was also cured in a position of the light-emitting surface 503 in which the weight 311 and the normal vector 313 were parallel to one another. Correspondingly, the lens shape shown in FIG. 7 then forms. The corresponding optoelectronic lighting device has here the reference sign 703.

Compared to this, the applied lens material for producing the lens 801 according to FIG. 8 was cured by analogy with FIG. 6 in a position in which the weight 311 and the normal vector 313 were antiparallel to one another. Correspondingly, the lens shape that is shown in FIG. 8 forms for the cured lens 801, which is more flattened compared to lens shape of the cured lens 701 according to FIG. 7. A corresponding aspect ratio is to this extent lower than an aspect ratio of the cured lens 701.

To produce the lens 701 according to FIG. 7 and produce the lens 801 according to FIG. 8, 20 mg of curable lens material were applied in each case to the light-emitting surface 503. In an example not shown, a height of a dam with respect to the light-emitting surface 503 is 500 μm. A diameter 315 for both lenses 701, 801 is, for example, 4 mm.

FIG. 9 shows an optoelectronic lighting device 901.

The optoelectronic lighting device 901 comprises an optoelectronic semiconductor component 103 having a light-emitting surface 905. A curable lens material 909 has been applied to this light-emitting surface 905.

A normal vector of the light-emitting surface 905 oriented in the direction of the applied lens material 909 is indicated by the reference sign 911. A weight that acts on the light-emitting surface 905 is provided with the reference sign 907.

The weight 907 can be divided into a normal force 913 and a tangential force 915. The normal force 913 is perpendicular or orthogonal to the light-emitting surface 905. The tangential force 915 is parallel or tangential to the light-emitting surface 905.

In FIG. 9, the light-emitting surface 905 is in a position in which the normal force 913 of the weight 907 is antiparallel to the normal vector 911.

FIG. 10 shows the optoelectronic lighting device 901, the light-emitting surface 905 being located here in a position in which the normal force 913 and the normal vector 911 are parallel to one another.

We therefore provide the concept of curing, in particular baking, a lens dispensed on a light-emitting surface of an optoelectronic component overhead (normal vector and normal force or weight parallel to one another). In an advantageous way, this produces lens geometries that cannot be achieved if the applied lens material is baked or generally cured upright. Upright refers here to a position in which the weight and normal vector are antiparallel to one another. A parabolic shape of the lens is possible in an advantageous way by the overhead position. On the other hand, generally only a flattened hemisphere can be achieved as a lens shape by upright curing.

With the dispensed amount of lens material it is possible in an advantageous way, for example, for a lens shape to be influenced or set within a wide range. The weight of the dispensed lens material has the effect in the hanging state (overhead) of a stretching of the lens material and, as a result, a significantly increased aspect ratio (height/diameter) of the lens. In an advantageous way, higher lenses than in the case of the conventional method of baking, or generally curing, in an upright or normally level position can consequently be created. In an advantageous way, the dispensing operation allows commercially available silicones, which are not necessarily designed for molding (injection molding), to be used.

Therefore, greater lens heights can be achieved, which in an advantageous way increase an outcoupling of light perpendicularly to the light-emitting surface, which may also be formed as the surface of a chip.

In particular, a greater range of variation of the lens shape is obtained by the hanging curing orientation, in particular baking orientation. Consequently, exact setting of an emission behavior of the optoelectronic semiconductor component can be made possible in an advantageous way.

In particular, it is possible in an advantageous way for standard dispensable silicones to be used.

Although our methods and devices have been more specifically illustrated and described in detail by the preferred examples, this disclosure is not restricted by the examples disclosed, and other variations may be derived from them by those skilled in the art without departing from the scope of protection of the appended claims.

This application claims priority of DE 10 2015 107 516.4, the subject matter of which is incorporated herein by reference.

1-8. (canceled)

9. A method of producing a lens for an optoelectronic lighting device, wherein the optoelectronic lighting device comprises an optoelectronic semiconductor component having a light-emitting surface, comprising:
applying a curable lens material to the light-emitting surface, and
curing the lens material to form a lens from a cured lens material, wherein
after the application and before or during the curing, the light-emitting surface is arranged into a position in which a normal vector of the light-emitting surface oriented in the direction of the applied lens material and a normal force of a weight acting on the light-emitting surface are parallel to one another so that the lens material at least partially cures in the position.

10. The method according to claim 9, wherein the weight is substantially perpendicular to the light-emitting surface so that the normal vector corresponds substantially to the weight.

11. The method according to claim 9, wherein, before the application, a dam running at least partially around the light-emitting surface is formed for the lens material to be applied.

12. The method according to claim 11, wherein the dam has a height of 400 μm to 600 μm with respect to the light-emitting surface.

13. The method according to claim 9, wherein, before the arranging of the light-emitting surface into the position, the applied lens material is pre-cured.

14. The method according to claim 9, wherein the pre-curing and/or the curing comprises irradiation of the applied lens material with electromagnetic radiation and/or heating of the lens material to a temperature of 140° C. to 160° C., for a time of 3400 s to 3800 s.

15. The method according to claim 9, wherein 10 mg to 20 mg of curable lens material is applied to the light-emitting surface.

16. A method of producing a lens for an optoelectronic lighting device, wherein the optoelectronic lighting device comprises an optoelectronic semiconductor component having a light-emitting surface, comprising:
applying a curable lens material to the light-emitting surface, and
curing the lens material to form a lens from a cured lens material, wherein
after the application and before or during the curing, the light-emitting surface is arranged into a position in which a normal vector of the light-emitting surface oriented in the direction of the applied lens material and a normal force of a weight acting on the light-emitting surface are parallel to one another so that the lens material at least partially cures in the position,
before the application, a dam running around the light-emitting surface completely so that the dam is therefore uninterrupted, is formed for the lens material to be applied.

17. An optoelectronic lighting device, comprising:
an optoelectronic semiconductor component having a light-emitting surface, and
a lens formed on the light-emitting surface from a lens material having at least partially cured in a position in which a normal vector of the light-emitting surface oriented in the direction of a lens material applied to the light-emitting surface and a normal force of a weight acting on the light-emitting surface are parallel to one another.
